(19) United States
(12) Patent Application Publication
(10) Pub. No.: US 2010/0019858 A1
(43) Pub. Date: Jan. 28, 2010

(54) N:M TRANSFORMER AND IMPEDANCE MATCHING

(75) Inventors: Robert J. McMorrow, Concord, MA (US); Pavel Bretchko, Reading, MA (US); Hanching Fuh, Waltham, MA (US); Raymond J. Shumovich, Roxbury, MA (US)

Correspondence Address: WOLF GREENFIELD & SACKS, P.C., 600 ATLANTIC AVENUE, BOSTON, MA, 02210-2206, US

(73) Assignee: Star RF, Inc., Waltham, MA (US)

(21) Appl. No.: 12/417,132

(22) Filed: Apr. 2, 2009

Related U.S. Application Data
(60) Provisional application No. 61/135,696, filed on Jul. 22, 2008.

(51) Int. Cl. H03H 11/28; H01F 27/28

(52) U.S. Cl. 333/32; 336/200

(57) ABSTRACT

Impedance matching techniques can be used to match an amplifier to an antenna for signal transmission. Some impedance matching techniques use an integrated passive component and an integrated transformer. Some impedance matching techniques include the use of an integrated n:m transformer, where n≠m. Several n:m transformer implementations are described.

### RELATED APPLICATIONS

This application claims priority under 35 U.S.C. §119(e) to U.S. Provisional Application Ser. No. 61/135,696, entitled “Impedance Matching,” filed on Jul. 22, 2008, which is hereby incorporated by reference in its entirety.

### BACKGROUND

1. Technical Field

The techniques described herein relate to electrical circuits and techniques for impedance matching at radio frequencies.

2. Discussion of Related Art

Radio frequency (RF) signals are widely used for wireless communication. A transmitter is used to transmit radio waves and a receiver receives the radio waves to extract an encoded message. Message transmission is performed by amplifying the radio frequency signal to drive an antenna. Impedance matching to the antenna is used to efficiently transfer power to the antenna and reduce reflections back into the amplifier. Several impedance matching techniques are known, examples of which are shown in FIGS. 1-5.

FIG. 1 shows a prior circuit 10 having an impedance matching circuit 14 coupled to an amplifying element 11. Amplifying element 11 amplifies a tuned version of input signal Vᵢₙ to produce an amplified signal V_{dd}, which has a waveform 12. Following the amplifying element 11, circuit 10 also includes a harmonic matching circuit 13, an impedance matching circuit 14, and a low-pass filter 15. Harmonic matching circuit 13 reduces the unwanted harmonics produced by amplifying element 11. Impedance matching circuit 14 matches the amplifier output impedance to the impedance of an antenna, which is represented by load impedance 16. Low-pass filter 15 filters the amplified signal to produce the output signal Vₒᵤₜ having sinusoidal waveform 17.

FIG. 2 shows an implementation of circuit 10 in which circuits 13-15 include inductors and capacitors 21 arranged in a ladder network. In this implementation, inductors and capacitors 21 are arranged in a low pass configuration. Inductor 22 isolates the power supply Vₛᵤₚ from the circuit 10. Inductor 22 may be large enough to function as an RF choke and have minimal effect on the AC circuit. Capacitor 23 blocks the DC component from the load impedance 16 and may be large enough to have minimal effect on the AC circuit.

FIG. 3 shows an example of a prior multi-primary bridge amplifier 30 that combines the signal power provided by push-pull amplifiers 31 and 32. Push-Pull amplifiers 31 and 32 transfer energy into primary windings 33 and 34, respectively, of transformers 37 and 38. The secondary windings 35 and 36 of transformers 37 and 38 are coupled in series across primaries 33 and 34 so that the power is combined constructively and delivered to the load impedance R_{L}. Since each of the transformers 37 and 38 has a 1:1 turns ratio, the impedance transformation is such that each push-pull amplifier 31 and 32 sees a reduced impedance: the load impedance divided by the number of primaries (R_{L}/a, where a is the number of primaries). FIG. 3b shows the output stage transistors of each push-pull amplifier 31 and 32. Each transistor sees an impedance of half the impedance across a primary (R_{L}/2a). Matching capacitors (not shown) can be used to tune out transformer leakage inductance. The transformers can alternatively be designed to have a center tap to provide for injection of a DC bias voltage.

FIG. 4 shows another example of a prior multi-primary bridge amplifier 40 that includes four push-pull amplifiers and four 1:1 transformers. Since bridge amplifier 40 includes four primary windings and all of the secondary windings are connected in series, each primary winding sees an impedance of R_{L}/4.

FIG. 5 shows a two-stage multi-primary bridge amplifier 50 according to another prior technique. The two-stage multi-primary bridge amplifier 50 includes a first stage multi-primary bridge 40 followed by a second multi-primary bridge 30. Connecting two stages of multi-primary bridges spreads out the impedance matching over two stages.

### BRIEF DESCRIPTION OF DRAWINGS

FIG. 1 shows a prior circuit architecture having an output matching network coupled to an amplifying element.

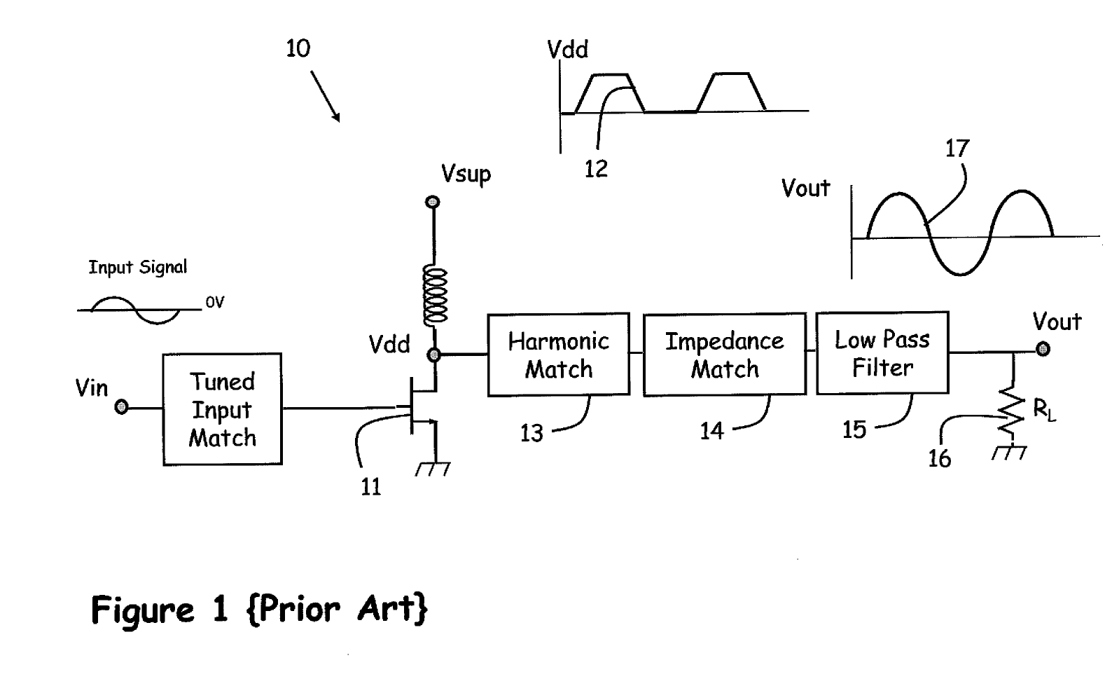

FIG. 2 shows an implementation of circuit of FIG. 1 that includes inductors and capacitors arranged in a ladder configuration.

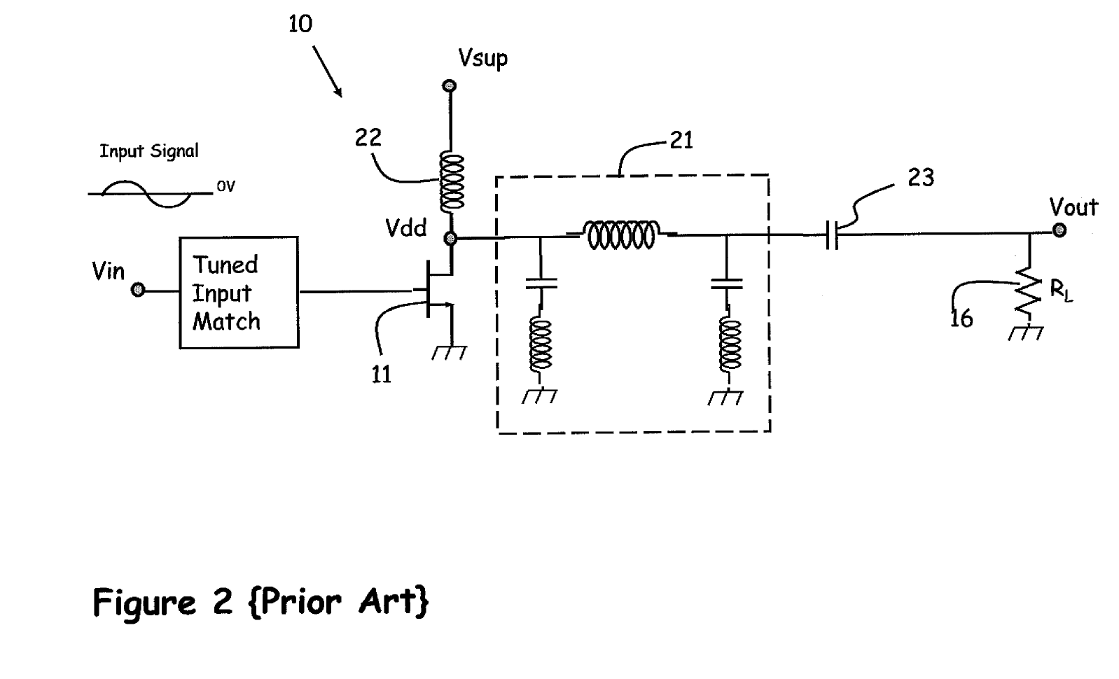

FIG. 3 shows a prior multi-primary bridge amplifier that combines the signal power provided by two push-pull amplifiers.

FIG. 4 shows another prior multi-primary bridge amplifier that includes four push-pull amplifiers and four 1:1 transformers.

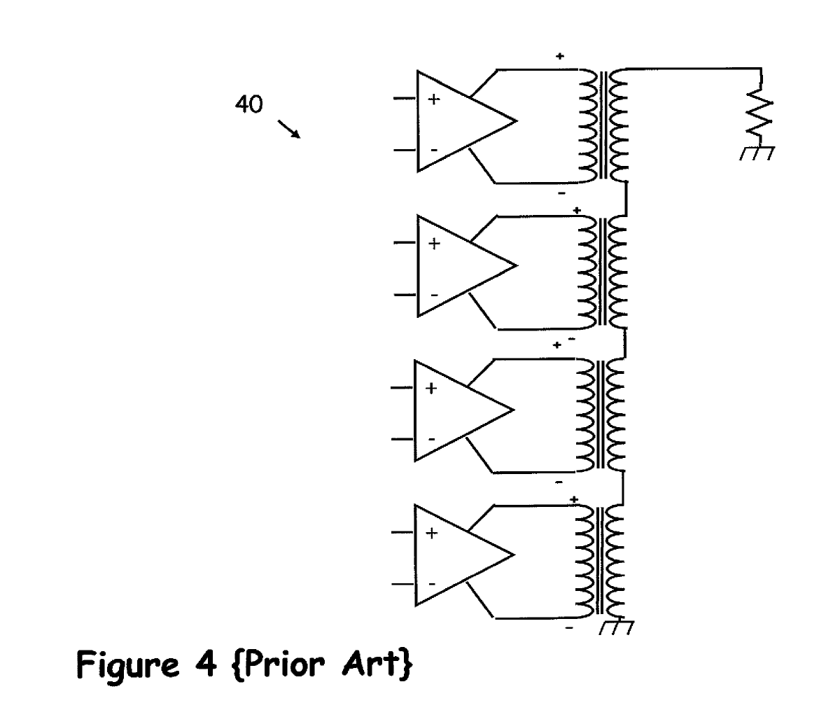

FIG. 5 shows a two-stage multi-primary bridge amplifier according to another prior technique.

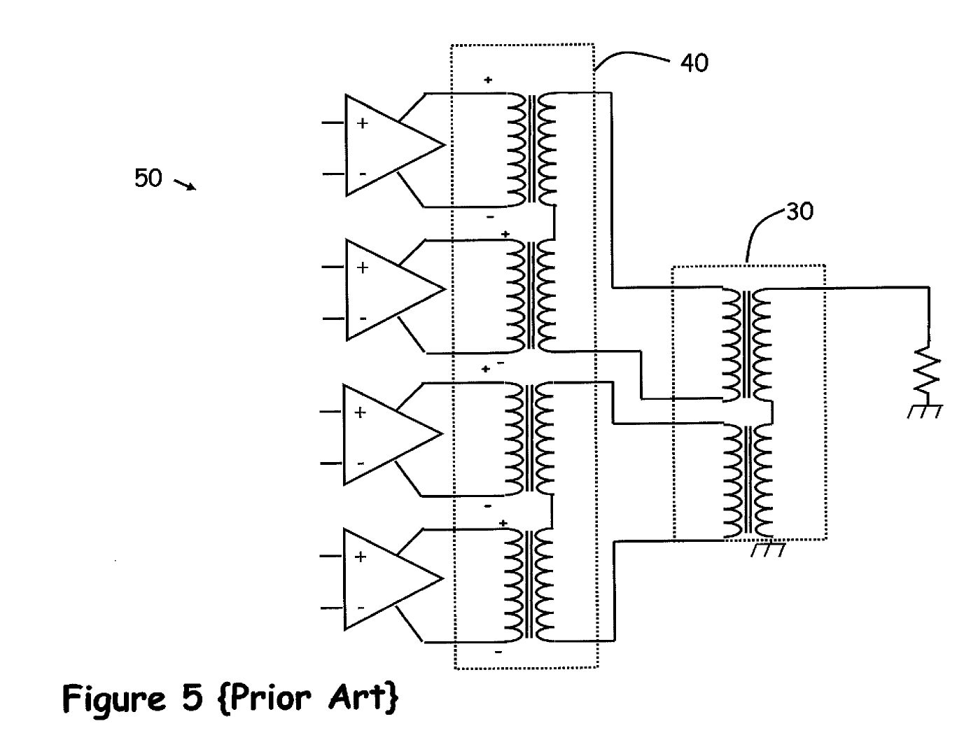

FIG. 6 shows an embodiment of an impedance matching network that includes both integrated passive components and integrated transformers.

FIG. 7 shows an embodiment in which the circuit of FIG. 6 is modified to include tuning circuits.

FIG. 8 shows an embodiment of an impedance matching network in which primary windings are coupled in parallel, creating an effective 1:2 transformer.

FIG. 9 shows an embodiment of an impedance matching network in which four primary windings are coupled in parallel, creating an effective 1:4 transformer.

FIG. 10 shows an embodiment of an impedance matching network that includes both integrated passive components and an n:m transformer.

FIG. 11 shows the circuit of FIG. 10 in which tuning circuits have been added in series between the amplifiers and the integrated passive components.

FIG. 12 shows a modified schematic representation of the circuit of FIG. 11 showing primary windings coupled in parallel and secondary windings coupled in series.

FIG. 13 shows a modified schematic representation of the circuit of FIG. 12.

FIG. 14 shows a generalized schematic of the circuits of FIGS. 11-13 showing the transformers as having a 1:2 turns ratio.

FIG. 15 shows an embodiment of an n:m transformer network that may be formed in a planar integrated circuit process.

FIG. 16 shows an embodiment of an n:m transformer network that takes up a relatively small area.

FIG. 17 shows an embodiment of an n:m transformer network having multiple primary conductors coupled in parallel.

FIG. 18 shows an embodiment of an n:m transformer network having multiple primary and secondary conductors coupled in parallel.

FIG. 19 shows an embodiment of an n:m transformer network having roughly a 2:1 aspect ratio.

FIG. 20 shows an embodiment of an n:m transformer network having roughly a 2:1 aspect ratio and having a cross-coupled secondary to cancel magnetic flux.

FIG. 21 shows an embodiment in which a capacitor is coupled between portions of a primary transformer winding.

FIG. 22 shows an embodiment in which a switch is coupled between portions of a primary transformer winding.

FIG. 23 shows an embodiment in which a primary winding capacitor is formed within the area of the transformer.

FIG. 24 shows an embodiment in which connections to the primary and secondary windings are formed through a single side of the transformer.

### DETAILED DESCRIPTION

Techniques for impedance matching and transformation at RF frequencies are described herein, including exemplary integrated circuits, transformers, and impedance matching methods. These techniques may be used for impedance matching an RF power amplifier to an antenna for the wireless transmission of an RF signal. Several methods of signal transmission are described herein, which may be used in a variety of wireless applications such as cellular telephones, for example. In some situations, an RF power amplifier may have a relatively small impedance and an antenna or other load may have a relatively large impedance. Such a situation may arise when an RF power amplifier operates in class DE mode, which may cause the amplifier's output impedance to be relatively low. The techniques described herein can provide a high degree of impedance transformation for impedance matching at RF frequencies, among other advantages.

### Matching Networks with Integrated Passive Component(s) and Integrated Transformer(s)

In some embodiments, an integrated transformer and an integrated passive component cooperate to perform impedance matching. For example, an integrated passive component may perform a first stage of impedance matching and an integrated transformer may perform a second stage of impedance matching. Using both an integrated transformer and integrated passive component can provide a high degree of impedance transformation, and in some embodiments, such a circuit can take advantage of component reduction techniques, examples of which are described below.

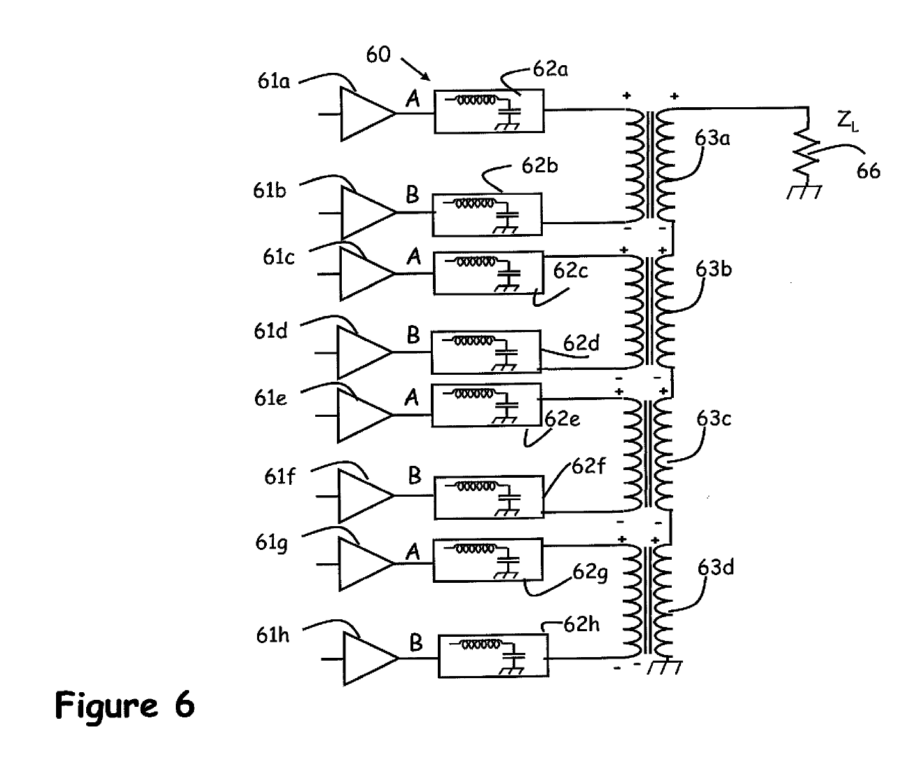

FIG. 6 shows an embodiment of a circuit 60 having an impedance matching network that includes integrated passive components 62a-h and integrated transformers 63a-d. Amplifiers 61a-h may be power amplifiers that are each coupled to one of the integrated passive components 62a-h. An integrated passive component 62 includes at least one integrated inductor and/or at least one integrated capacitor, which may be coupled in a ladder configuration or other configuration. The primary windings (left side) of integrated transformers 63a-d are each coupled to two integrated passive components 62a-h. As illustrated in FIG. 6, the secondary windings of integrated transformers 63 are coupled in series with one another such that their combined outputs are delivered to a load impedance 66. Load impedance 66 may represent an antenna that transmits the combined outputs of the secondary windings.

Amplifiers 61a-h may produce differential signals that are shifted in phase with respect to each other by approximately 180°. For example, amplifiers 61a, 61c, 61e, and 61g may each produce a signal with substantially the same waveform (e.g., waveform A), which is delivered to a positive terminal of one of the integrated transformers 63a-d through one of the integrated passive components 62a, 62c, 62e, or 62g. Amplifiers 61b, 61e, 61f, and 61h may each produce a signal with substantially the same waveform (e.g., waveform B) which may be phase-shifted with respect to signal A by approximately 180°. These four signals of waveform B may each be delivered to a negative terminal of one of the integrated transformers 63a-d through one of the integrated passive components 62b, 62d, 62f, or 62h. Amplifiers 61a-h do not necessarily share any terminal connections like traditional push-pull amplifiers (e.g., push-pull amplifiers 31 and 32), because amplifiers 61a-h may each be implemented by a separate amplifier, in some embodiments. If each of amplifiers 61a-h is implemented by a separate amplifier, an amplifier pair (e.g. 62a and 62b) can function substantially as a push-pull amplifier and their output power can be combined by differentially driving one of the primary windings of integrated transformers 63a-d.

Amplifiers 61a-h deliver signals to integrated passive components 62a-h to perform a first stage of impedance transformation. For example, integrated passive components 62a-h may receive a signal from an amplifier at a first port and transform the output impedance of amplifiers 61a-h seen at the first port into a higher or lower impedance at a second port of the integrated passive component. In some embodiments, amplifiers 61a-h may be operable in a class DE mode of operation, and may have a relatively low output impedance. Such a low output impedance may be transformed by integrated passive components 62a-h into a higher impedance in order to ultimately achieve an impedance match with the load impedance 66. However, integrated passive components 62a-h may perform only part of the impedance transformation, and the signal output of integrated passive components 62a-h may be delivered to integrated transformers 63a-d for further impedance transformation.

In some embodiments, a second stage of impedance transformation may be performed by integrated transformers 63a-d. The primary windings of integrated transformers 63a-d may receive the outputs of integrated passive components 62a-h. To combine the power of the differential signals A and B, the transformed versions of waveform A may be delivered to the positive terminals of the primary windings and the transformed versions of waveform B may be delivered to negative terminals of the primary windings. As a result, the outputs of the integrated passive components 62a-h differentially drive the primary windings of integrated transformers 63a-d. Integrated transformers 63a-d have secondary windings that are coupled in series, thereby combining the signal power of the eight received signals. The impedance seen at the output of each integrated passive component is combined such that the load impedance 66 sees the combined impedance, which is eight times higher than the impedance provided by one of the integrated passive components 62. From the point of view of the amplifiers 61a-h, the load impedance Z_{L} is transformed by transformers 63a-d into separate impedances of Zₐ=Z_{L}/8 at the integrated passive components 62a-h. Zₐ is then further transformed by the ladder networks to an impedance of Z_{b} at each of the amplifiers 61, where Z_{b}=Zₐ/K. The value K is selectable based on the design of the integrated passive components 62a-h. In general, K may be greater than, equal to or less than one, based on whether the integrated passive component 62 is designed to be a high-pass, low-pass, or band-pass network. The use of an integrated passive component in addition to an integrated transformer may allow for greater flexibility with regard to selection of the transformed load impedance seen by each amplifier, as well as harmonic matching and mode of operation. In addition, a two-stage matching network can have a broader bandwidth than prior matching networks, in some embodiments.

The implementation of suitable integrated passive components 62 and integrated transformers 63 will be understood by one of ordinary skill in the art, taking into account the techniques described herein. In some embodiments, all of the integrated passive components 62a-h may be identical, however, the techniques described herein are not limited in this respect, as non-identical integrated passive components may alternatively be used. Similarly, each of integrated transformers 63a-d may be identical to one another, although non-identical integrated transformers may be used alternatively. In the example shown in FIG. 6, each of the integrated transformers 62a-h has a 1:1 turns ratio. However, in some embodiments described in further detail below, one or more of the transformers may have a turns ratio that is different from 1:1, such as an n:m turns ratio where n≠m.

The embodiment illustrated in FIG. 6 includes four 1:1 transformers and eight integrated passive components; however, a larger or smaller number of transformers and integrated passive components may be used depending on the application. For example, more transformers and integrated passive components may be used to deliver a higher amount of power to the load impedance, or fewer may be used to deliver less power. Any suitable number of primaries may be used. If single-ended signals are used rather than differential signals, the number of integrated passive components may be reduced by half. In some embodiments, one or more components of an integrated passive component 62 may be combined with tuning inductor(s) (not shown) used to tune out the transformer leakage inductance. In some embodiments, the transformer primary windings may include a center tap to inject DC bias.

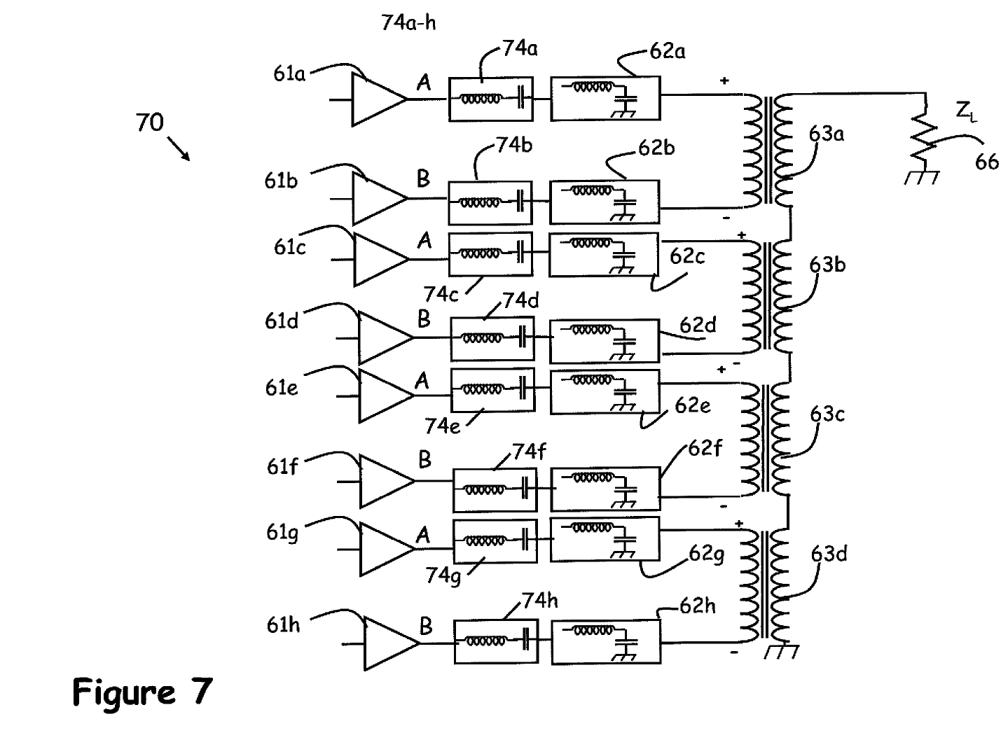

FIG. 7 shows an embodiment of a circuit 70 having the impedance matching network of FIG. 6, and further including tuning circuits 74a-h between the amplifiers 61 and the integrated passive components 62. A tuning circuit 74 may tune an amplifier 61 to a class DE or other mode of operation, and may perform harmonic shaping and filtering. Tuning circuit 74 may be an L-C resonator circuit, or any other suitable circuit. In some embodiments, component(s) can be combined to reduce the total number of components used for in the circuit. For example, due to the architecture of circuit 70, one or more components of a tuning circuit 74 and one or more components of an integrated passive component 62 may be combined, thus saving chip area.

### Impedance Matching with n:m Transformer (n≠m)

In some embodiments, an integrated transformer having an n:m turns ratio can used to perform impedance matching, where n≠m. As one example, an integrated 1:2 transformer is described which may provide an increased impedance transformation capability over a conventional 1:1 transformer, in some embodiments. Using an integrated n:m transformer may allow for the use of fewer amplifiers for the same amount of impedance transformation, thus saving power and chip area.

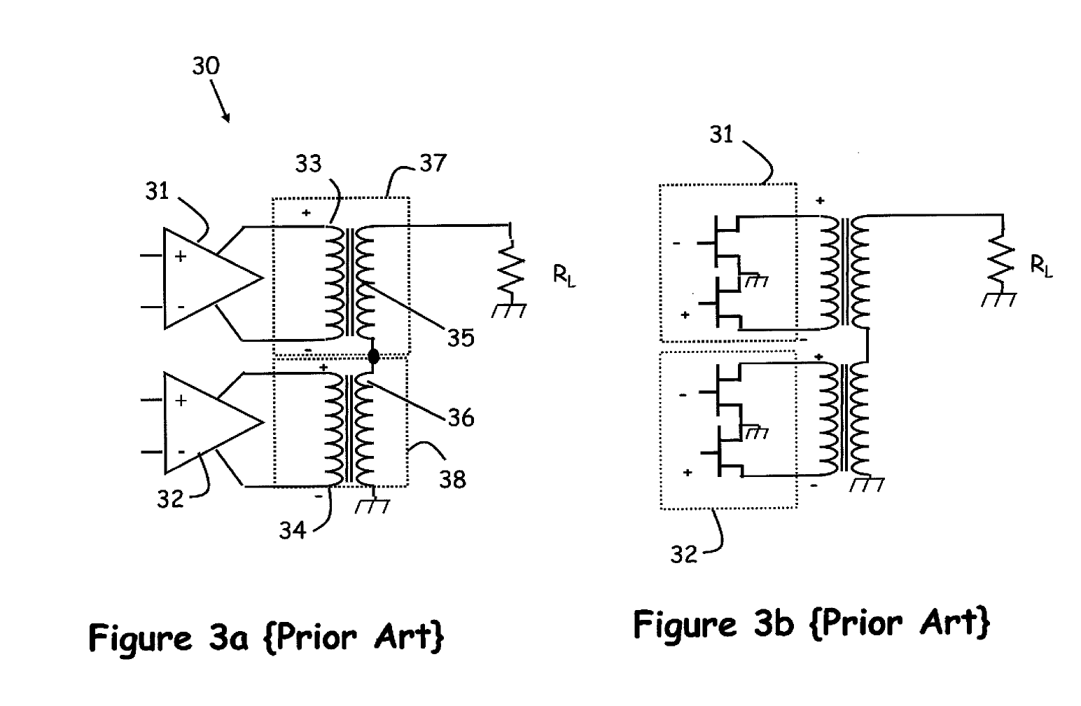

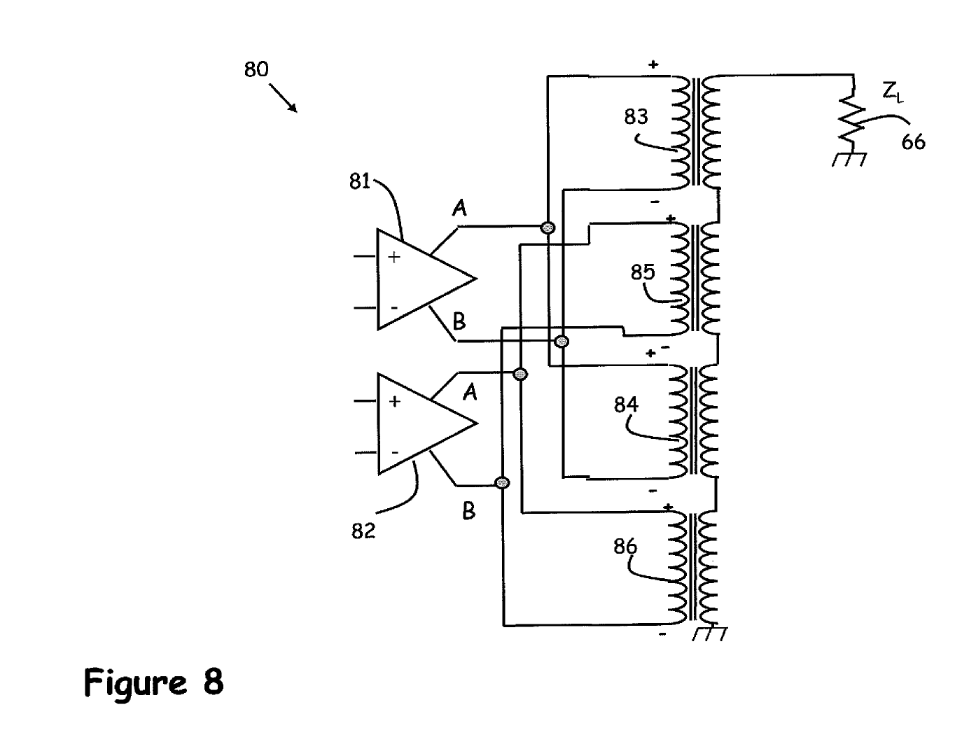

FIG. 8 shows an embodiment of a circuit 80 having an impedance transformation network that includes four 1:1 transformers 83-86 in which two pairs of primary windings are coupled in parallel, thus effectively forming two 1:2 transformers. Push-pull amplifier 81 drives both primary windings of transformers 83 and 84, and push-pull amplifier 82 drives both primary windings of transformers 85 and 86. As shown in FIG. 8, the secondary windings of transformers 83-86 are coupled in series so that the signals delivered to the primary windings combine constructively (in-phase) to drive load impedance 66. This parallel primary configuration effectively doubles the number of secondary turns driven by each push-pull amplifier. Unlike the configuration of FIG. 3, which has the limitation that the impedance transformation is linearly proportional to the number of primary windings that are independently driven (Zₐ=Z_{L}/a, where a is the number of independently-driven primary windings), the impedance transformation network of FIG. 8 is not limited in this respect.

An n:m transformer can take advantage of the property that the impedance transformation performed by the transformer is proportional to the square of the turns ratio. For the effective two 1:2 transformers of FIG. 8, each push-pull amplifier will drive an impedance of Zₐ=Z_{L}/(2·n²)=R_{L}/8. For example, if the load impedance Z_{L}=50Ω, then each amplifier will see a transformed load impedance of Zₐ=6.25Ω. The impedance seen by an amplifier may be calculated using the equation Zₐ=R_{L}/(a·n²) for a push-pull amplifier driving two outputs, and Z_{L}=R_{L}/(2·a·n²) for a single ended amplifier that drives one end of a primary winding.

An effective 1:2 integrated transformer can be implemented in various ways, examples of which are described in further detail below. In some embodiments, an effective 1:2 transformer can be realized by connecting two 1:1 transformers in the manner illustrated in FIG. 8, in which the primary windings are connected in parallel and the secondary windings are connected in series.

In some embodiments, a 1:2 integrated transformer can be implemented using a transformer that does not have a 1:1 turns ratio. For example, one primary turn may be electromagnetically coupled to two secondary turns. Such a transformer may be physically realized in a variety of ways, examples of which are described below. These techniques may be extended to achieve any suitable n:m turns ratio where n≠m, using 1:1 transformers suitably coupled and/or a transformer that electromagnetically couples a non-unity ratio of turns. The terms n:m turns ratio, n:m transformer and similar terms are intended to encompass either of these techniques.

The overall impedance transformation capability of the matching network illustrated in the embodiment of FIG. 8 (factor of eight) may be the same as the impedance transformation capability of the embodiment illustrated in FIG. 6. One advantage of the embodiment of FIG. 8 is that the same matching capability may be realized with a fewer number of amplifiers, thus saving power and chip area. This n:m transformer technique may be extended to include more or less than two independently-driven primary windings, some examples of which are discussed below. As should be appreciated from the above discussion of FIG. 6, various modifications may be made. For example, independent amplifiers may be substituted for push-pull amplifiers 81 and 82, and driven out of phase so as to function as push-pull amplifiers. In some implementations, capacitor(s) may be coupled to the primary windings and/or the secondary windings to tune out the transformer leakage inductance.

In some embodiments, transformers of different turns ratios may be used. For example, a first transformer may have an n:m turns ratio and a second transformer may have a p:q turns ratio, where n≠m, p≠q, and the ratio n:m is different from the ratio p:q. The secondaries of these transformers may be connected in series to drive the same load impedance. Many different combinations of transformers of different turns ratios may be used.

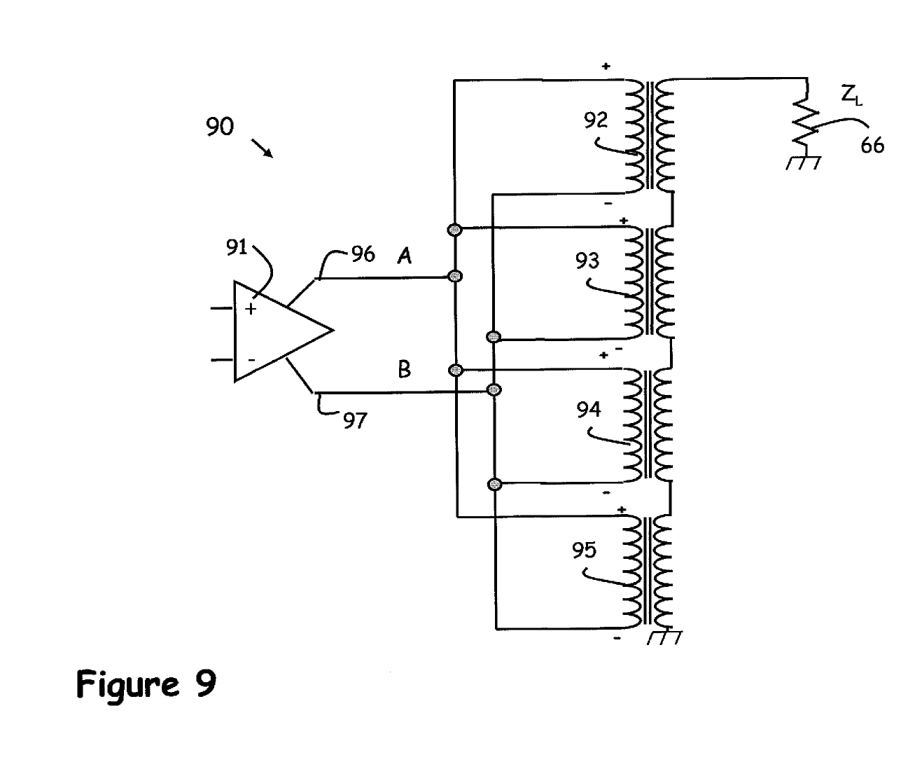

FIG. 9 shows an embodiment of a circuit 90 having an impedance transformation network that includes four 1:1 integrated transformers 92-95 having their primary windings connected in parallel and their secondary windings connected in series, thus effectively forming a 1:4 transformer. Push-pull amplifier 91 has a positive output terminal 96 that drives the positive sides of the primary windings of transformers 92-95 and a negative output terminal 97 that drives the negative sides of primary windings of transformers 92-95. Similar to FIG. 8, the secondary windings of transformers 92-95 are coupled in series so that the signals delivered to the primary windings combine constructively to drive load impedance 66. This configuration may effectively quadruple the number of turns that the secondary winding presents to the primary winding.

For the effective 1:4 transformer of FIG. 8, push-pull amplifier 91 drives an impedance of Zₐ=Z_{L}/(n²)=R_{L}/8. The overall matching capability of the matching network illustrated in FIG. 9 may be the same as that of the circuits illustrated in FIG. 6 and FIG. 8 (factor of eight). One advantage of the circuit of FIG. 9 is that the same matching capability may be achieved with only a single push-pull amplifier 91. Such an implementation may be used where the load impedance 66 is to be driven with less power than in the embodiment of FIG. 8. Using a smaller number of amplifiers may be more efficient than using more amplifiers, as a single amplifier operating at its maximum power may be more efficient than two amplifiers operating at 50% power level, Various modifications may be made to the circuit of FIG. 9 such as those described above with respect to FIG. 8.

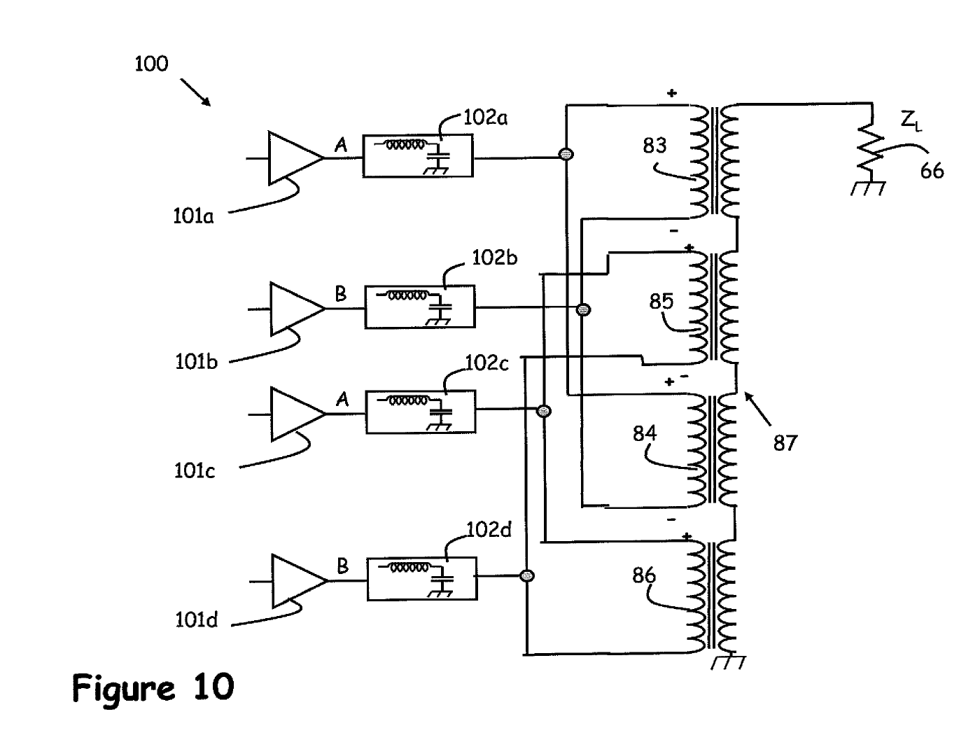

FIG. 10 shows a circuit 100 having an impedance transformation network in which integrated passive components 102a-d are connected in series between amplifiers 101a-d and the primary windings of transformers 83-86, resulting in an impedance transformation network having four integrated passive components and two 1:2 transformers. The circuit may combine the advantages of the multi-stage impedance transformation network of circuit 60 (FIG. 6) and an effective n:m transformer (FIG. 8). Such advantages may include a greater impedance transformation capability and component reduction. It should be appreciated that integrated passive components and effective n:m transformers may be combined in a variety of ways other than that shown in FIG. 10, and that FIG. 10 is merely exemplary.

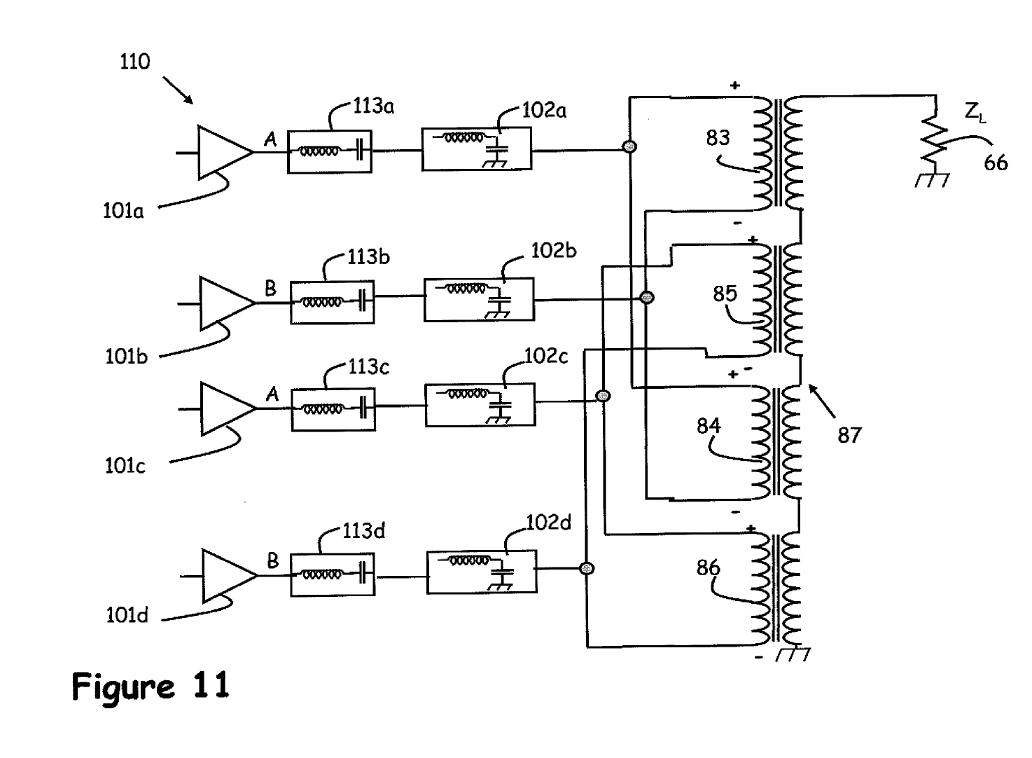

FIG. 11 shows a circuit 110 that is a modification of circuit 100 (FIG. 10) in which tuning circuits 113a-d have been added in series between the amplifiers 101a-d and the integrated passive components 102a-d. As discussed above with respect to FIG. 7, a tuning circuit 113 may provide harmonic shaping and filtering, and may tune an amplifier 101 to a class DE mode of operation in some embodiments.

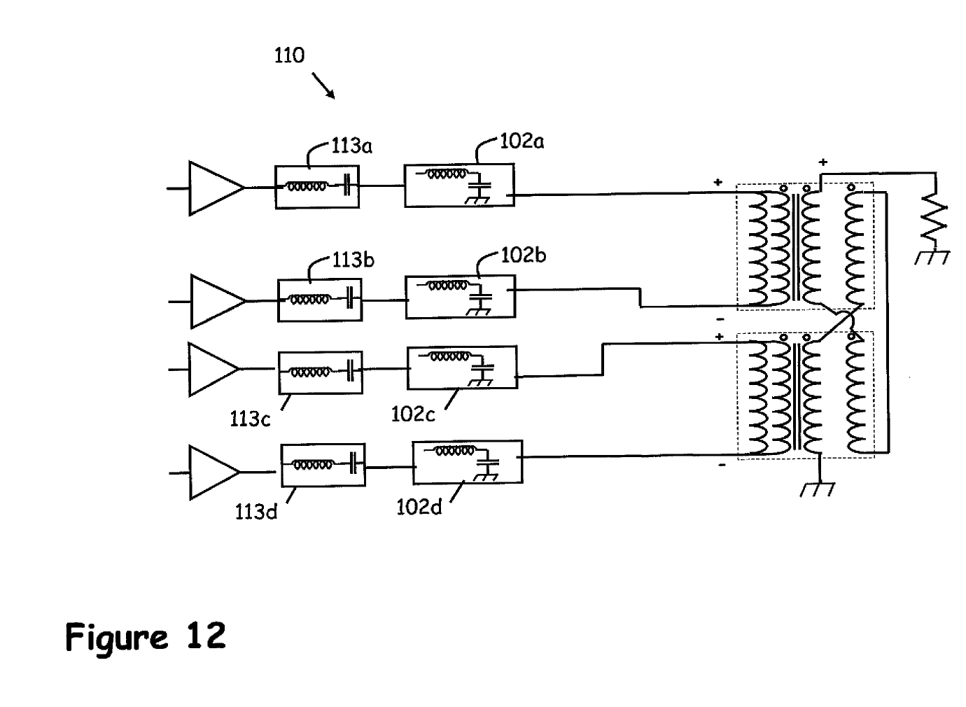

FIG. 12 shows a modified schematic representation of circuit 110 (FIG. 11) in which the four 1:1 transformers are replaced by two transformers, each of which has two primary and two secondary windings. The circuit in FIG. 12 is functionally the same as circuit 110 of FIG. 11, but is shown with a different circuit representation. A voltage applied to the primary winding may induce a substantially equivalent voltage in each of the secondary windings. Since the secondary windings are connected in series, the total voltage on a transformer's secondary winding may be twice as large as it is on a transformer's primary winding. Due to conservation of energy, the current through the transformer's secondary winding may be half of the current in transformer's primary winding.

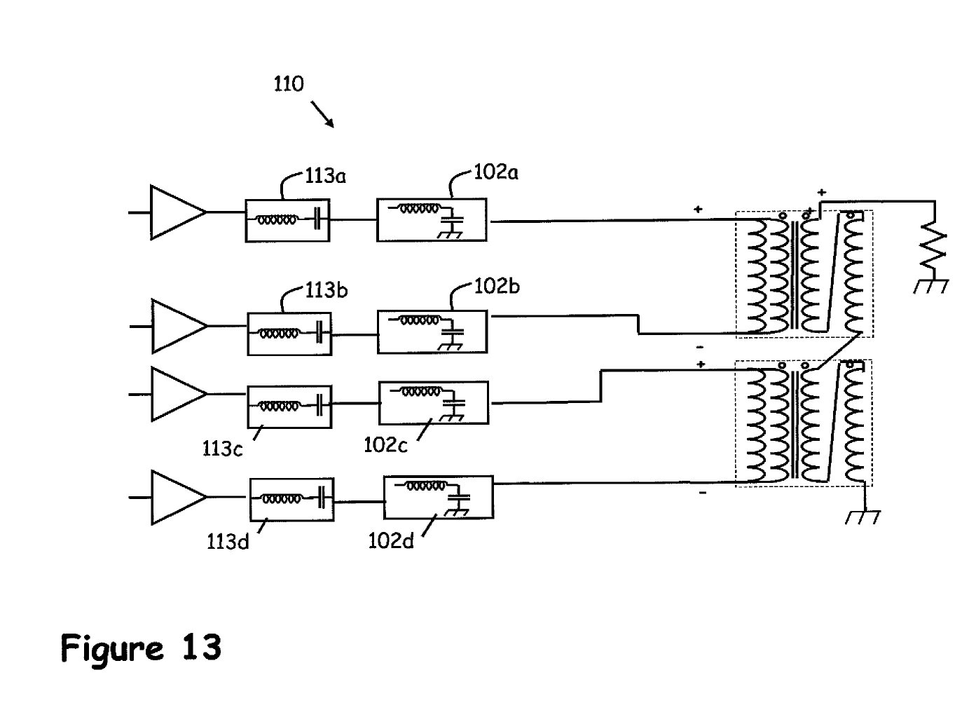

FIG. 13 shows a modified schematic representation of circuit 110 (FIG. 12). Assuming that parasitics in each of the transformers are small, the currents in each of the secondary windings may be approximately equal, allowing the circuit of FIG. 12 to be re-drawn. In FIG. 13, the secondaries of each transformer are connected in series before they are connected to another transformer. This approach may be extended to any suitable transformer combination that realizes a turns ratio of n:m.

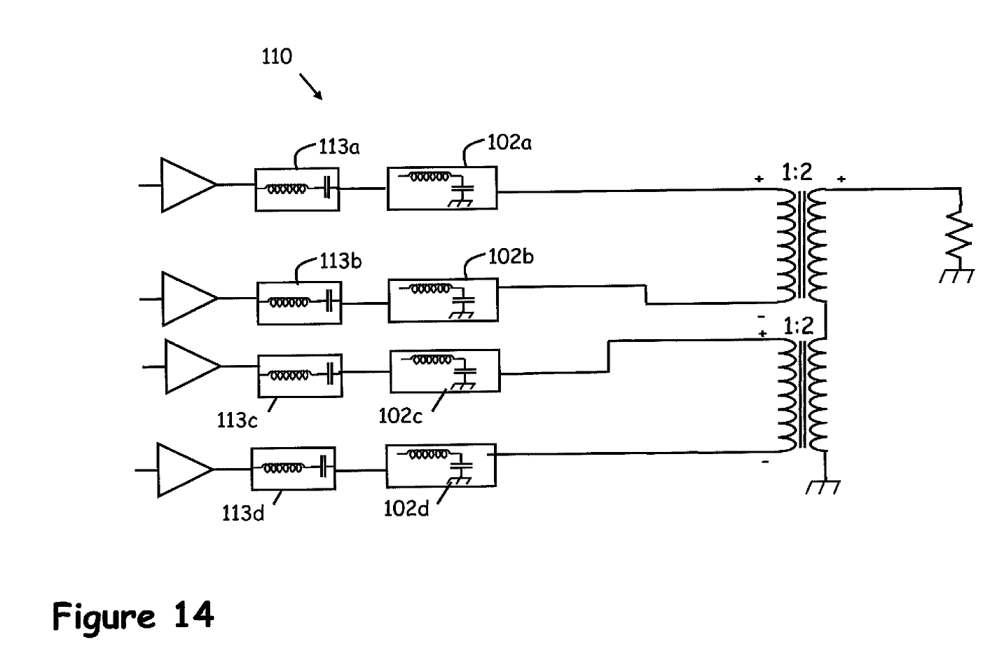

FIG. 14 shows a generalized schematic of the circuits of FIGS. 11-13 showing that the parallel-primary configuration of FIG. 11 may be represented as two transformers each having a 1:2 turn ratio.

### Embodiments of n:m Transformers

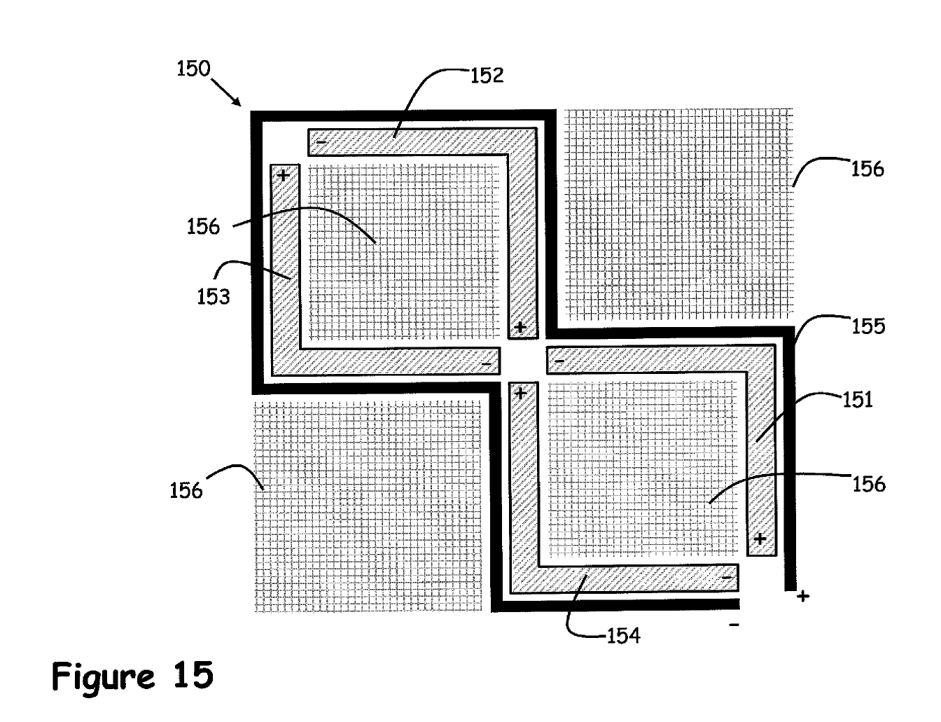

FIG. 15 shows an embodiment of an n:m transformer network 150 that may be formed in a planar integrated circuit process. Transformer network 150 includes two 1:2 transformers that may be used to implement the two effective 1:2 transformers illustrated in FIGS. 8 and 10-14. Transformer network 150 includes four primary windings, of which primary windings 151 and 154 may be coupled in parallel and primary windings 152 and 153 may be coupled in parallel, although the parallel connections are not shown for clarity. Primary windings 151-154 may be formed as transmission lines in some embodiments. The primaries and the secondary may be substantially planar. The secondary winding 155 is arranged to be electromagnetically coupled to each primary winding. In the embodiment of FIG. 15, secondary 155 surrounds all of the primaries, however, secondary 155 need not surround all of the primaries or any of the primaries, as other implementations can be realized.

The primaries and secondary may be substantially formed in the same plane or in different planes. For example, the primaries and secondary may all be formed in the same metallization level of an integrated circuit of any suitable conductive material. In some embodiments, a portion of transformer network 150 may be formed in another metallization level, as the invention is not limited in this respect. For example, in some implementations the primaries may be formed in a first metallization level and the secondary may be formed in a second metallization level.

Transformer network 150 may be formed in any suitable manufacturing process such as CMOS (Complementary Metal Oxide Semiconductor). To make effective use of the chip area, active circuitry 156 may optionally be formed adjacent to and/or within the area of transformer network 150. Such active circuitry may be formed in the same manufacturing process as transformer network 150. Amplifiers may be connected to the transformer network 150 by series transmission lines, which may serve as a portion of an integrated passive component 102 and/or a tuning network 113 (FIG. 11), in some embodiments,

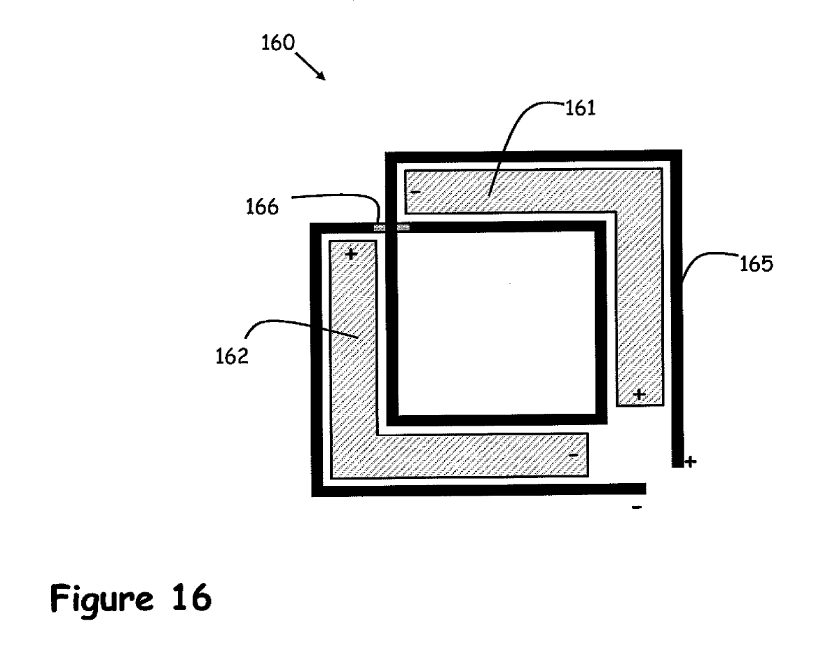

FIG. 16 shows another embodiment of an n:m transformer network 160. Transformer network 160 includes two 1:2 transformers that may be used to implement the two effective 1:2 transformers illustrated in FIGS. 8 and 10-14. Transformer network 160 has a secondary 165 that is wound twice around the primary transmission lines 161 and 162. As shown in FIG. 16, secondary 165 has two turns, one of which is formed within the area of primary transmission lines 161 and 162, and one of which is formed outside this area. An underpass (or overpass) metal connection 166 provides a connection between different portions of the secondary 165 where secondary 165 crosses over itself. One advantage of transformer network 160 is that it may be relatively compact and take up a relatively small amount of chip surface area.

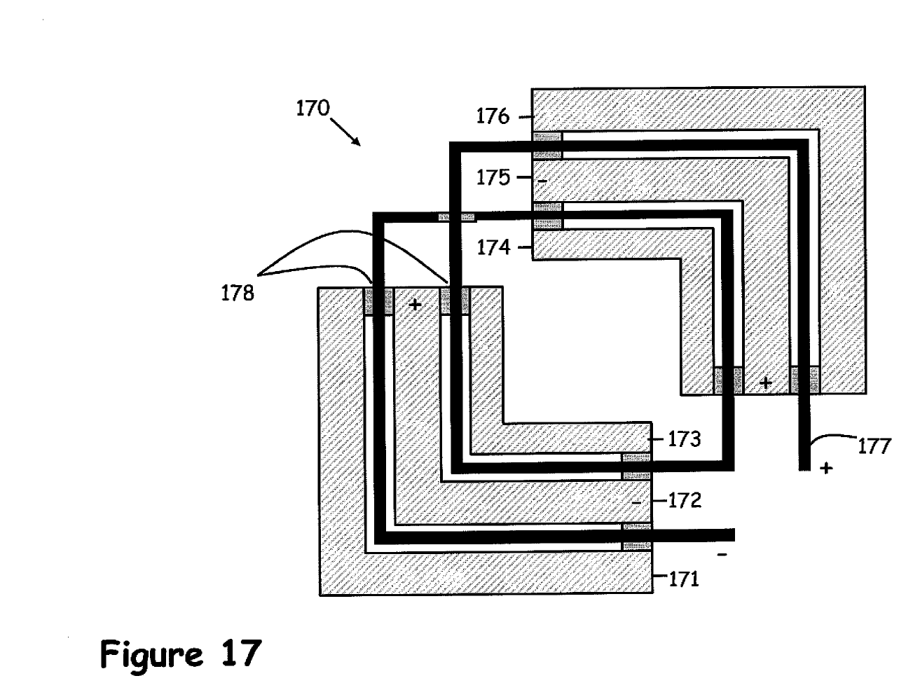

FIG. 17 shows another embodiment of an n:m transformer network 170. Like transformer network 160, transformer network 170 includes two 1:2 transformers, and has a secondary 177 that is wound twice around primary transmission lines. In this embodiment, each set of primary transmission lines is coupled in parallel to improve coupling to the secondary winding 177. Primary transmission lines 171-173 are connected in parallel, and primary transmission lines 174-176 are connected in parallel. These parallel connections may be made through underpass (or overpass) metal connections 178, only some of which are labeled in FIG. 17 for clarity. Although connecting multiple ideal transformer windings in parallel does not provide a benefit according to linear circuit models, such linear models do not take into account the non-linear skin effect that takes place at high frequencies. At RF frequencies, most of the conductor current may flow in the area closest to the edge of the conductor due to the skin effect. Having multiple conductors in coupled parallel creates additional paths for the current to flow as a result of the increased surface area. In addition, since the primaries are now coupled to the secondary on both sides of the secondary, the total coupling coefficient may be higher. This layout may be extended to a different number of parallel primary windings to control the coupling coefficient and reduce transformer loss by increasing the total area of the conductor edges.

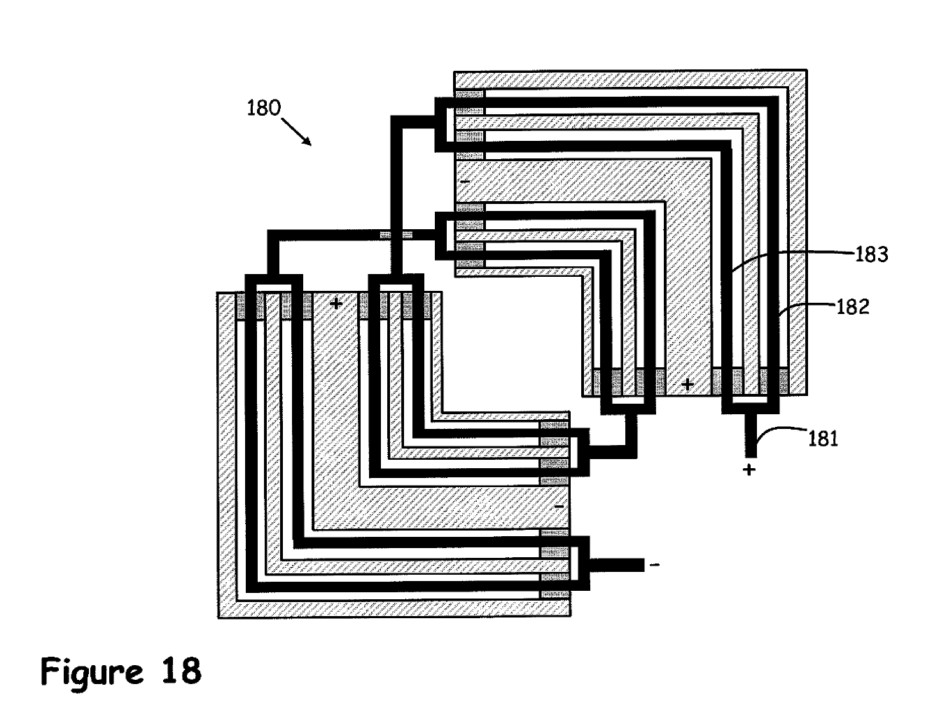

FIG. 18 shows another embodiment of an n:m transformer network 180. Like n:m transformer network 170, transformer network 180 includes two 1:2 transformers, and has a secondary 181 that is wound twice around primary transmission lines. In this embodiment, secondary 181 includes sections that are split into parallel portions, such as parallel portions 182 and 183. As discussed above with respect to FIG. 17, having multiple conductors in parallel may create additional paths for the current to flow, and may increase coupling and decrease loss. The optimal number of primaries and/or secondary portions coupled in parallel may be governed by particular design rules for a given semiconductor process. However, any suitable number of primary and/or secondary portions may be coupled in parallel, as the invention is not limited in this respect.

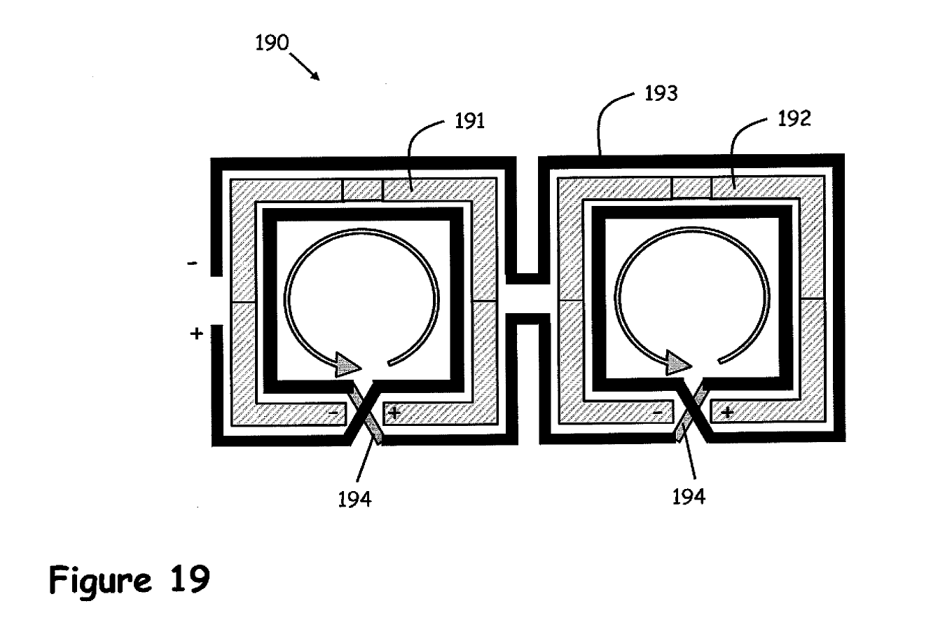

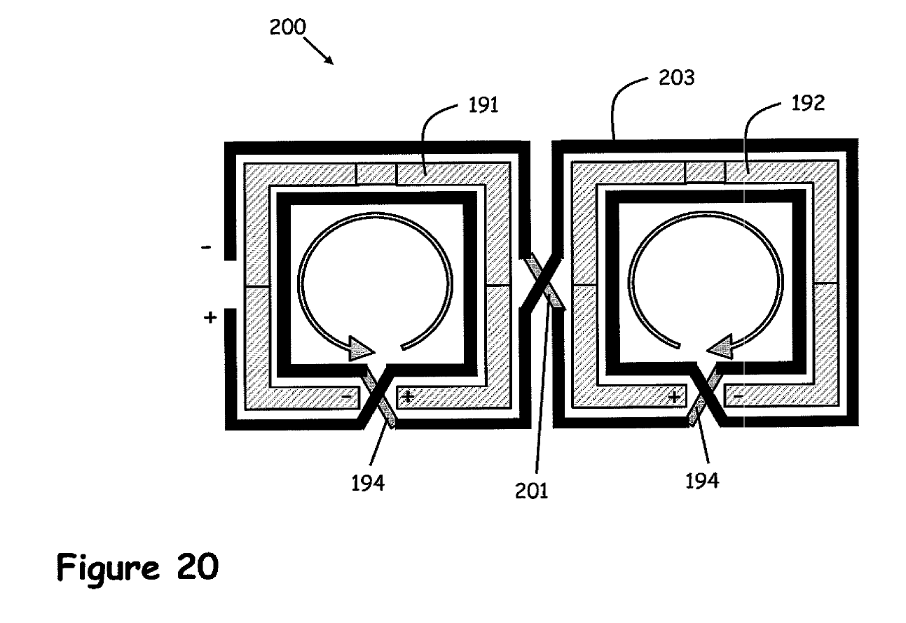

FIG. 19 shows another embodiment of an n:m transformer network 190 that includes two 1:2 transformers. Transformer network 190 may have a roughly 2:1 aspect ratio, in contrast to the transformers of FIGS. 17 and 18 which may have a roughly 1:1 aspect ratio. The aspect ratio may be chosen according to chip layout considerations or other factors. Transformer network 190 includes primaries 191 and 192 which may be formed around different areas of an integrated circuit, and may substantially surround and/or subtend their respective areas. Transformer network 190 includes a secondary 193 that may have a figure-eight-like shape. In the embodiment of FIG. 19, a first turn of secondary 193 surrounds a first area of the integrated circuit within the area occupied by primary 191. A second turn of the secondary 193 surrounds a second area of the integrated circuit within the area occupied by primary 192. A third turn of the secondary 193 surrounds primary 192. A fourth turn of secondary 193 surrounds primary 191. Underpass (or overpass) connections 194 connect various segments of secondary 193 where it crosses over itself Although the embodiment illustrated in FIG. 19 includes two primary windings, it should be appreciated more or fewer than two primary windings may be used in other implementations, as the techniques described herein are not limited to any particular number of primary windings. The primaries may surround and/or subtend more or fewer than two areas. In the embodiment of FIG. 19, the currents in both sections of the transformer flow in the same counterclockwise direction, inducing magnetic flux in the same direction in both areas of the transformer, thus causing a superposition of this magnetic flux. To reduce the flux, the secondary can be arranged so that the current flows in opposite directions, as illustrated in FIG. 20.

FIG. 20 shows another embodiment of an n:m transformer network 200 in which portions of secondary 203 are cross-coupled so that the current in the two areas of the secondary flows in opposite directions (i.e., clockwise in one portion and counterclockwise in another portion). As a result, the magnetic flux outside of the transformers may be substantially canceled, thus creating less interference with other circuitry on chip. In transformer 200, the cross-coupling may be achieved using an underpass (or overpass) connection 201 in the middle of the transformer network 200 that reverses, with respect to transformer network 190, the direction of the current flow in the portion of the secondary on the right side of the transformer network.

### Component Reduction

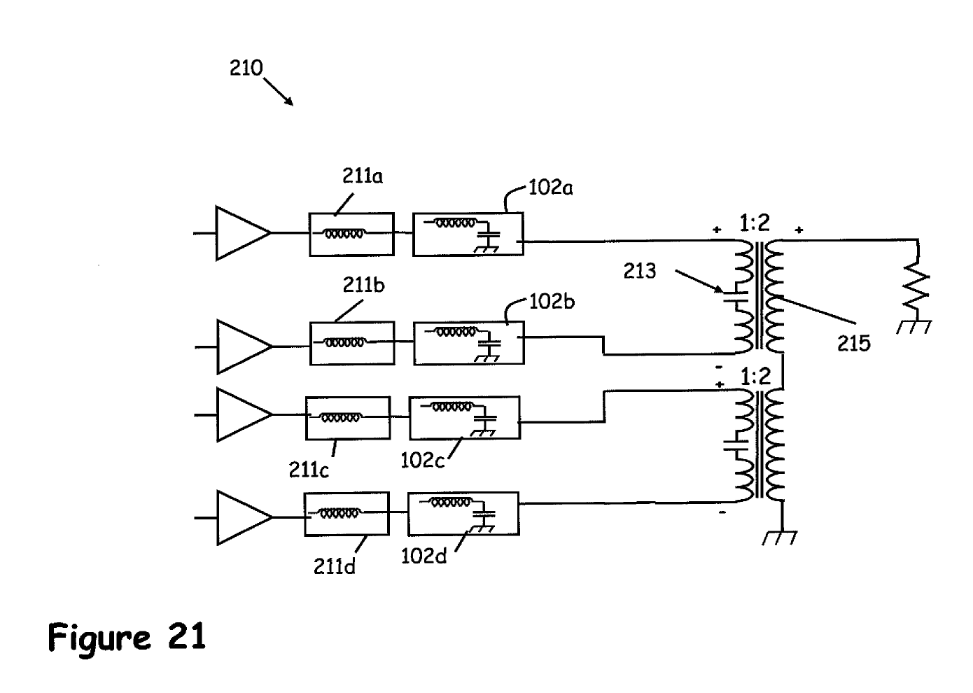

FIG. 21 shows an embodiment of a circuit 210 in which the circuit of FIG. 14 has been modified according to an exemplary component reduction technique. In this embodiment, the series capacitors in the L-C tuning networks 113 of FIG. 14 have been moved to the other side of the integrated passive components 102. The two capacitors eliminated for each integrated passive component 211 have been replaced by a capacitor 213 between two portions of the primary winding of transformer 215. Capacitor 213 may have half the value of the capacitor of an L-C tuning network 113, as a result of the series combination of the two capacitors. Capacitor 213 may be placed in the middle of primary winding of the transformer 215. One advantage of this approach is a smaller-value capacitor, which can reduce chip area. Another advantage is that this capacitor can be placed under or over the transformer 215, reducing chip area.

### Switched Primary

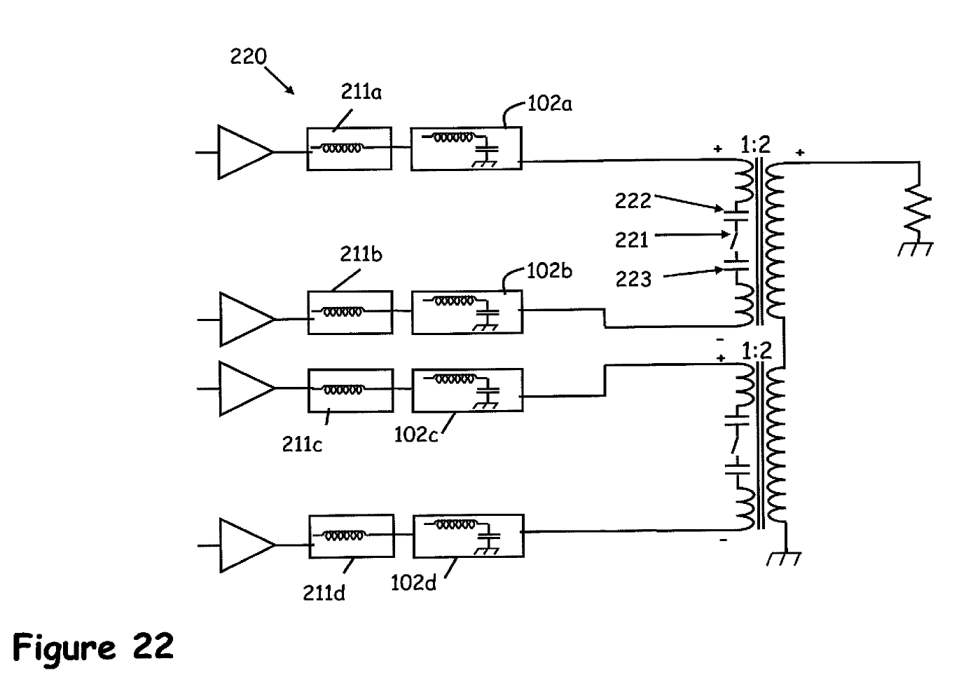

FIG. 22 shows an embodiment of a circuit 220 having a switch 221 coupled in series with a transformer primary winding. Such a switch 221 may provide isolation of the amplifier from the secondary winding of transformer in some circumstances. Such a switch may be useful in a mode of operation in which one or more amplifiers are turned off. One example is a multi-band RF transmitter in which a multiplexer is used to switch between different bands. Using the proposed architecture for the output transformer in conjunction with a switched capacitor in the primary winding may make design of the multiplexer simpler, as the impedance loading from the primary windings of the transformer may no longer be present when the switch is turned off.

In some embodiments, splitting the capacitor 213 (FIG. 20) into two capacitors 222 and 223 may allow for the switch to be placed at a virtual ground node, assuming that the primaries of the transformer are driven by complimentary signals, which may simplify control of the switch. Another advantage is that smaller signals may be present across the switch, which may reduces stress on the switch.

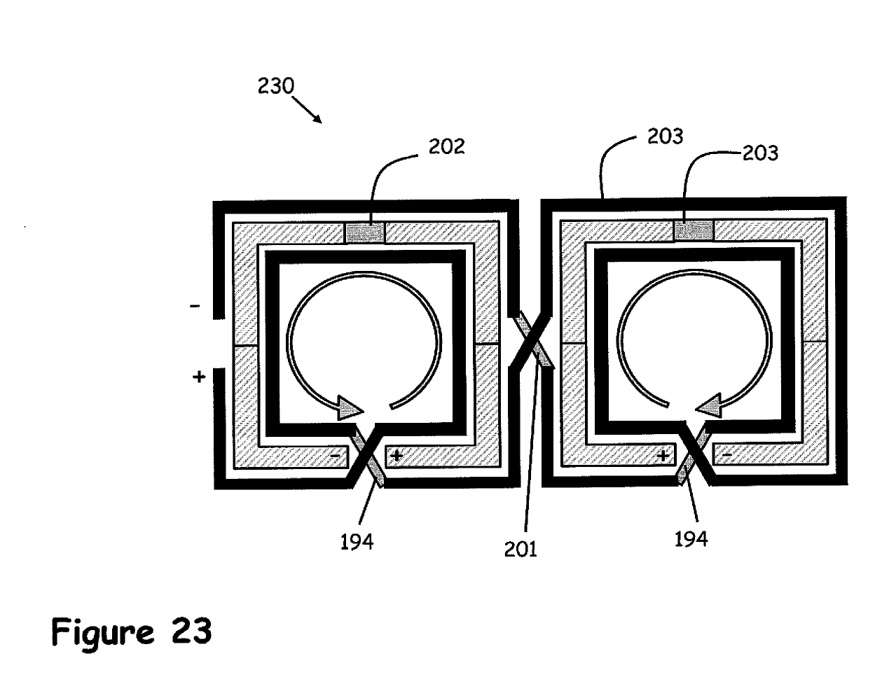

FIG. 23 shows an embodiment of an n:m transformer network 230 similar to n:m transformer network 200 with the exception that capacitors 202 and 203 have been added between portions of the primaries, as in circuit 220. Capacitors 202 and/or 203 may be formed below or above the level of the primaries such that they do not extend beyond the perimeter of n:m transformer network 230, thus saving chip area. The formation of such a capacitor is within the capabilities of one of ordinary skill in the art based on the techniques described herein. In some embodiments, switch 201 may be formed below the primaries and within the area of the n:m transformer network 230.

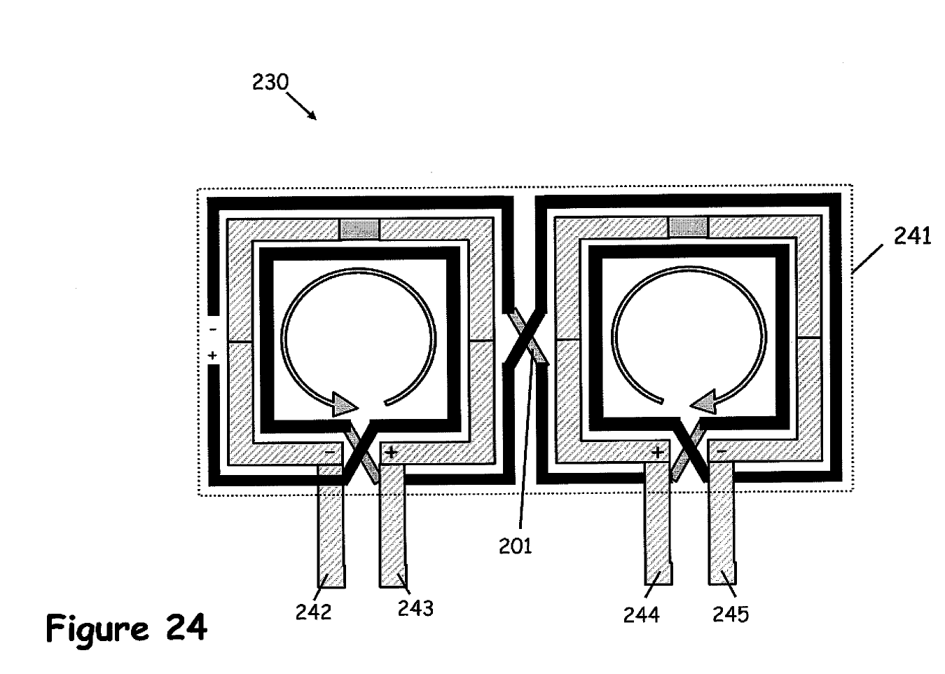

FIG. 24 shows an embodiment in which connections are made to the primary windings of transformer network 230 on a single side of the transformer network. Forming all of the connections on the same side of the transformer network may save space on the substrate. As shown in FIG. 24, transformer network 230 may have substantially the shape of a rectangle 241. Connections 242-245 may pass through a single side of the rectangle (e.g., bottom side) to reach the primary windings.

As used herein, the terms “radio frequency” and “RF” refer to frequencies within the range of 500 kHz to 300 GHz, such as between 500 MHz and 300 GHz. In some embodiments, the techniques described herein may be used at higher frequencies, as the invention is not limited in this respect. As used herein, the term “integrated” with respect to a circuit element may refer to the circuit element being formed with other integrated circuit elements as part of a chip, such as a semiconductor chip, for example. Such a circuit element may be formed in any suitable integrated circuit manufacturing process, such as CMOS. Any number of chips may be used, such as one chip or more than one chip. For example, one or more integrated components may be formed on one chip and connected to one or more other integrated components formed on another chip. In some implementations, an integrated transformer may not be formed on a semiconductor chip. For example, the primary and/or secondary windings of an integrated transformer may be formed as metal traces on a different kind of substantially planar substrate, such as a printed circuit board.

Having thus described some illustrative embodiments of the invention, it should be apparent to those skilled in the art that the foregoing is merely illustrative and not limiting, having been presented by way of example only. Numerous modifications and other illustrative embodiments may be contemplated by those of ordinary skill in the art and are believed to fall within the scope of the invention.

Use of ordinal terms such as “first,” “second,” “third,” etc. in the claims to modify a claim element or item in the specification does not by itself connote any priority, presence or order of one element over another. In addition, the use of an ordinal term does not by itself connote a maximum number of elements having a certain name that can be present in a claimed device or method. Any suitable number of additional elements may be used unless a claim requires otherwise. Ordinal terms are used in the claims merely as labels to distinguish one element having a certain name from another element having a same name. The use of terms such as “at least one” or “at least a first” in the claims to modify a claim element does not by itself connote that any other claim element lacking a similar modifier is limited to the presence of only a single element. Any suitable number of additional elements may be used unless a claim requires otherwise. The use of “including,” “comprising,” or “having,” “containing,” “involving,” and variations thereof herein, is meant to encompass the items listed thereafter and equivalents thereof as well as additional items.

What is claimed is:

1. An integrated n:m transformer for radio frequency impedance matching, wherein n≠m, and the integrated n:m transformer comprises:
a primary winding comprising at least one first conductor on a substrate; and
a secondary winding comprising at least one second conductor on the substrate, the at least one first and second conductors being constructed and arranged to establish an n:m turns ratio with respect to the primary winding and the secondary winding, wherein n≠m

2. The integrated n:m transformer of claim 1, wherein the secondary winding comprises more turns than the primary winding.

3. The integrated n:m transformer of claim 1, wherein the primary winding comprises a first plurality of conductors coupled in parallel and/or the secondary winding comprises a second plurality of conductors coupled in parallel, wherein the first plurality of conductors comprises the at least one first conductor and the second plurality of conductors comprises the at least one second conductor.

4. The integrated n:m transformer of claim 1, wherein the primary winding and the secondary winding are formed substantially in the same metallization level.

5. The integrated n:m transformer of claim 1, wherein the primary winding and the secondary winding are formed in different metallization levels on the substrate.

6. The integrated n:m transformer of claim 1, wherein the secondary winding comprises a first turn and a second turn that are both coupled to the primary winding

7. The integrated n:m transformer of claim 5, wherein the first turn is formed on a first side of the at least one first conductor and the second turn is formed on a second side of the at least one first conductor, the first side being different from the second side.

8. The integrated n:m transformer of claim 1, wherein the primary winding is formed around a first area of the integrated circuit, and the integrated n:m transformer further comprises:
a second primary winding formed around a second area of the integrated circuit, wherein the first and second areas do not overlap with one another; and wherein the secondary winding comprises a first turn formed around the first area and a second turn formed around the second area.

9. The integrated n:m transformer of claim 8,
wherein the secondary winding comprises a third turn formed around the second area, and a fourth turn formed around the first area,
wherein the first primary winding is formed around the first turn of the secondary winding, and wherein the second primary winding is formed around the second turn of the secondary winding,
wherein the third turn of the secondary winding is formed around the second primary winding, and wherein the fourth turn of the secondary winding is formed around the first primary winding, and
wherein the first turn of the secondary winding surrounds the first area and the second turn of the secondary winding surrounds the second area.

10. The integrated n:m transformer of claim 8, wherein the first and second turns of the secondary winding are arranged such that the current in the first turn of the secondary winding flows in a first direction that is either clockwise or counterclockwise and the current in the second turn of the secondary winding flows in a second direction that is either clockwise or counterclockwise, wherein the first direction is opposite to the second direction.

11. The integrated n:m transformer of claim 8, wherein the integrated n:m transformer has an outer perimeter having substantially the shape of a rectangle, wherein connections to the first and second primary windings are made by a plurality of conductors that only pass through a single side of the rectangle.

12. An electrical circuit, comprising:
the integrated n:m transformer of claim 1, wherein the primary winding comprises a first conductor and a second conductor; and
at least one integrated capacitor that couples the first conductor of the primary winding to the second conductor of the primary winding.

13. The electrical circuit of claim 12, wherein the at least one integrated capacitor is formed beneath the primary winding within the outer perimeter of the integrated n:m transformer.

14. The electrical circuit of claim 12, wherein the at least one integrated capacitor is formed at a virtual ground node.

15. The electrical circuit of claim 13, fisher comprising:
a first impedance matching circuit coupled to the first conductor, the first impedance matching circuit comprising a first inductor;
a second impedance matching circuit coupled to the second conductor, the second impedance matching circuit comprising a second inductor;
wherein the first and second impedance matching circuits are LC impedance matching circuits coupled to share the at least one integrated capacitor as a resonant capacitive element.

16. An electrical circuit, comprising:
the integrated n:m transformer of claim 1, wherein the primary winding comprises a first conductor and a second conductor; and
a switch that couples the first conductor of the primary winding to the second conductor of the primary winding.

17. The electrical circuit of claim 16, wherein the switch is formed at a virtual ground node of the primary winding.

18. The electrical circuit of claim 16, further comprising:
an amplifier coupled to the primary winding;
wherein the switch is controllable to be turned off, thereby decoupling the amplifier from the secondary winding.

19. The electrical circuit of claim 16, further comprising:
a first capacitor coupled between the switch and the first conductor of the primary winding; and
a second capacitor coupled between the switch and the second conductor of the primary winding.

20. An electrical circuit, comprising:
the integrated n:m transformer of claim 1; and
a first differential amplifier comprising:
a first differential output coupled to a first terminal of the primary winding; and
a second differential output coupled to a second terminal of primary winding.

21. The electrical circuit of claim 20, further comprising:
a first integrated passive component coupled between the first differential output and the first terminal of the primary winding; and
a second integrated passive component coupled between the second differential output and the second terminal of the primary winding.

22. An electrical circuit, comprising:
the integrated n:m transformer of claim 20, wherein the integrated n:m transformer is a first integrated n:m transformer, the primary winding is a first primary winding and the secondary winding is a first secondary winding;
a second integrated n:m transformer comprising:
a second primary winding comprising at least one third conductor of the integrated circuit; and
a second secondary winding comprising at least one fourth conductor of the integrated circuit, the at least one third and fourth conductors being constructed and arranged to establish a p:q turns ratio with respect to the second primary winding and the second secondary winding, wherein p≠q;
wherein the first secondary winding is coupled in series with the second secondary winding.

23. The electrical circuit of claim 22, comprising more than two primary windings.

24. The electrical circuit of claim 22, wherein the first differential amplifier provides first and second differential signals to the first primary winding, and the electrical circuit Her comprises:
a second differential amplifier that provides third and fourth differential signals to the second primary winding;
wherein the first and third differential signals are substantially the same;
wherein the second and fourth differential signals are substantially the same;
wherein the first and third differential signals are shifted in phase by 180° with respect to the second and fourth differential signals.

25. The electrical circuit of claim 22, wherein n, m, p and q are positive integers,

26. The electrical circuit of claim 25, wherein the ratio n:m is different from the ratio p:q.

27. The electrical circuit of claim 25, wherein the ratio n:m is the same as the ratio p:q.

28. The electrical circuit of claim 20, wherein an antenna is coupled to the secondary winding to transmit a signal from the first differential amplifier.

29. A signal transmission method, comprising:
(A) driving an antenna using an amplifier that generates a radio frequency signal, the antenna having a first impedance; and
(B) transforming the first impedance using an integrated transformer having an n:m turns ratio, wherein n≠m, to produce a second impedance;
wherein the amplifier drives the antenna via the second impedance.

30. The method of claim 29, wherein the second impedance is smaller than the first impedance.

31. The method of claim 29, wherein the amplifier is a first amplifier, the integrated transformer is a first integrated transformer, the radio frequency signal is a first radio frequency signal, and the method further comprises:
(C) driving the antenna using a second amplifier that generates a second radio frequency signal; and
(D) transforming the first impedance using a second integrated transformer having a p:q turns ratio, where p≠q, to produce a third impedance;
wherein the second amplifier drives the antenna via the third impedance.

32. The method of claim 31 further comprising:
(E) controlling an amount of power delivered to the antenna by switching at least one switch that is coupled to at least one primary winding of the first and/or second integrated transformers.
